(19) United States
(12) Patent Application Publication
(10) Pub. No.: US 2007/0091953 A1
(43) Pub. Date: Apr. 26, 2007

(54) Light-emitting diode with a narrow beam divergence based on the effect of photonic band crystal-mediated filtration of high-order optical modes

(75) Inventors: Nikolai Ledentsov, Berlin (DE); Vitaly Shchukin, Berlin (DE)

Correspondence Address: BROWN & MICHAELS, PC;400 M & T BANK BUILDING, 118 NORTH TIOGA ST, ITHACA, NY, 14850, US

(73) Assignee: P.B.C LASERS LTD., Kibbutz Einat (IL)

(21) Appl. No.: 11/549,240

(22) Filed: Oct. 13, 2006

Related U.S. Application Data
(60) Provisional application No. 60/728,988, filed on Oct. 21, 2005.

(51) Int. Cl. H01S 5/00

(52) U.S. Cl. 372/43.01

(57) ABSTRACT

A semiconductor light-emitting diode having a low beam divergence includes at least one waveguide comprising an active region generating light by injection of a current, a photonic band crystal having the refractive index modulation in the direction perpendicular to the propagation of the emitted light, and at least one optical defect. The photonic band crystal and the optical defect are optimized such that the fundamental optical mode of the device is localized at the defect and decays away from the defect, while the other optical modes are extended over the photonic band crystal. The optical confinement factor of the localized optical mode preferably exceeds the optical confinement factor of the rest of the optical modes by at least a factor of three.

### REFERENCE TO RELATED APPLICATIONS

This application claims an invention which was disclosed in Provisional Application No. 60/728,988, filed Oct. 21, 2005, entitled “LIGHT-EMITTING DIODE WITH A NARROW BEAM DIVERGENCE BASED ON THE EFFECT OF PHOTONIC BAND CRYSTAL-MEDIATED FILTRATION OF HIGH-ORDER OPTICAL MODES”. The benefit under 35 USC §119(e) of the United States provisional application is hereby claimed, and the aforementioned application is hereby incorporated herein by reference.

### BACKGROUND OF THE INVENTION

1. Field of the Invention

The invention pertains to the field of semiconductor optoelectronic devices. More particularly, the invention pertains to a light-emitting diode with a low beam divergence.

2. Description of Related Art

A prior art light-emitting diode is shown in FIG. 1 (device (100)). The structure is grown epitaxially preferably on an n-doped substrate (101), and includes an n-doped region (102), a confinement layer (105), a p-doped region (108), and a p-contact layer (109). The confinement layer (105) further includes an active region, or a light generating region (106). The light generating region (106) emits light when a forward bias (113) is applied. Electrons from the n-doped region (102) and holes from the p-doped region (108) are injected into the confinement layer (105) and recombine in the light generating region (106), thereby emitting light. Light is generated, as a rule, in a broad spectrum of wavelengths in all spatial directions.

The substrate (101) is formed from any III-V semiconductor material or III-V semiconductor alloy. For example, GaAs, InP, GaSb, GaAs or InP are generally used depending on the desired emitted wavelength of laser radiation. Alternatively, sapphire, SiC or [111]-Si is used as a substrate for GaN-based lasers, i.e. laser structures, the layers of which are formed of GaN, AlN, InN, or alloys of these materials. The substrate (101) is doped by an n-type, or donor impurity. Possible donor impurities include, but are not limited to S, Se, Te, and amphoteric impurities like Si, Ge, Sn, where the latter are introduced under such technological conditions that they are incorporated predominantly into the cation sublattice to serve as donor impurities.

The n-doped layer (102) is formed from a material lattice-matched or nearly lattice-matched to the substrate (101), is doped by an n-impurity, and is preferably transparent to the emitted light in the spectral region, in which photons are generated in the active region (106). In the case of a GaAs substrate, the n-doped layer (102) is preferably formed from an n-doped GaAlAs alloy.

The p-doped layer (108) is formed from a material lattice-matched or nearly lattice-matched to the substrate (101), is doped by a p-impurity, and is preferably transparent to the emitted light in the spectral region, in which photons are generated in the light generating region (106). In the case of a GaAs substrate, the p-doped layer (108) is preferably formed from a p-doped GaAlAs alloy.

The p-contact layer (109) is preferably formed from a material lattice-matched or nearly lattice matched to the substrate, is transparent to the generated light, and is doped by an acceptor impurity. The doping level of the p-contact layer (109) is preferably higher than that in the p-doped layer (108).

The confinement region (105) is formed from a material lattice-matched or nearly lattice-matched to the substrate, is transparent to the emitted light, and is either undoped or weakly doped. In the case of a GaAs substrate, the preferred material is also GaAs.

The light generating region (106) placed within the confinement layer (105) is preferably formed by any insertion, the energy band of which is narrower than that of the substrate (101). Possible light generating regions (106) include, but are not limited to, a single-layer or a multi-layer system of quantum wells, quantum wires, quantum dots, or any combination thereof In the case of a device on a GaAs-substrate, examples of the active region (106) include, but are not limited to, a system of insertions of InAs, In₁₋ₓGaₓAs, InₓGa_{1-x-y}Al_{y}As, InₓGa₁₋ₓAs_{1-y}N_{y} or similar materials.

The n-contact (111) is contiguous with the substrate (101). A p-contact (112) is mounted on the p-contact layer (109).

The metal contacts (111) and (112) are preferably formed from multi-layered metal structures. The metal contact (111) is preferably formed from a structure including, but not limited to the structure Ni—Au—Ge. Metal contacts (112) are preferably formed from a structure including, but not limited to, the structure Ti—Pt—Au.

The p-contact layer (109) and the p-contact (112) are etched to form an optical aperture (132). Light generated in the active region comes out (123) through the optical aperture (132). A major shortcoming of conventional light-emitting diodes is that a large part of generated optical power is lost. Part of the generated light is directed into the substrate (121) and is absorbed in the metal contact (111). Another part of the generated light is directed at an angle exceeding the angle of the total internal reflection at the semiconductor/air boundary and is reflected back (122). This light also comes into the substrate and is absorbed in the contact. Only part of the generated light comes out (123).

Another disadvantage is a very broad angular far-field diagram of the outgoing light from the light-emitting diode. As typically a parallel light beam is needed, a light emitting diode is placed into a focus of a lens and covered by the lens from the top. A lens typically has a diameter of 2 to 3 mm, whereas a light-emitting diode typically has a diameter of 300 μm. Thus, if an array of light-emitting diodes on a panel is used, light is emitted only from a small fraction of the surface.

FIG. 2 shows another prior art light-emitting diode. The device (200) is selected to emit light in the edge-emitting geometry, through a side facet. The device includes an n-doped cladding layer (202), a waveguide (203), a p-doped cladding layer (208), and a p-contact layer (209). The waveguide (203) further includes an active region (206). The structure is grown epitaxially on an n-doped substrate (101).

The n-contact (111) is mounted on the substrate (101). The p-contact (212) is mounted on the p-contact layer (209). When a forward bias (113) is applied to the device, electrons and holes come to the active region (206) and recombine there, generating light. Light is generated in a plurality of optical modes. The waveguide length is selected preferably to be shorter than absorption length, so that light (223) impinging at a facet at an angle below the angle of the total internal refraction at the semiconductor/air interface can come out (215) of the device. Light, impinging on a facet at an angle larger than the angle of the total internal refraction, propagates to the substrate and bottom contact (221) or to the top contact (222) and is finally absorbed in the substrate and contact layers. The far-field diagram of the emitted laser light depends on the thickness of the waveguide (203). For a narrow waveguide, the emitted light has a broad far-field pattern.

If a waveguide is broad, the fundamental optical mode of the waveguide has a narrow far-field pattern. However, there exists a plurality of optical modes shown in FIGS. 3(a) through 3(c) having a comparable intensity. FIGS. 3(a) through 3(c) each show the fundamental optical mode (solid line). In addition, FIG. 3(a) also shows the second-order (dashed-dotted line) optical mode, FIG. 3(b) shows the fourth-order (dashed-dotted line) optical mode, and FIG. 3(c) shows the sixth-order (dashed-dotted line) optical mode. For any position of the active medium within the waveguide, several high-order modes have a comparable optical confinement factor within the active region. FIGS. 3(a) through 3(c) show that a few optical modes have comparable intensity throughout the entire waveguide, and no mode has a preference. Then the far-field pattern necessarily includes a contribution of a few high-order optical modes. Such a far-field pattern is wide and is most likely multi-lobe.

Therefore there is a need in the art for a light-emitting diode emitting light with a narrow far-field pattern.

### SUMMARY OF THE INVENTION

A semiconductor light-emitting diode having a low beam divergence is disclosed. The light-emitting diode includes at least one waveguide comprising an active region generating light by injection of a current, a photonic band crystal having refractive index modulation in the direction perpendicular to the propagation of the emitted light, and at least one optical defect. The active region is preferably placed within the optical defect. The photonic band crystal and the optical defect are optimized such that the fundamental optical mode of the device is localized at the defect and decays away from the defect, while the other optical modes are extended over the photonic band crystal. Localization of the fundamental mode at the defect results in the relative enhancement of the amplitude of the mode with respect to the other modes. Therefore, there is a larger optical confinement factor of the fundamental mode as compared to the optical confinement factor of the other modes. The optical confinement factor of the localized optical mode preferably exceeds the optical confinement factor of the rest of the optical modes by at least a factor of three, which ensures that the overall width of the light beam emitted by the light-emitting diode is predominantly defined by the localized optical mode having a low beam divergence, and thus has also a low beam divergence. This enables efficient single-mode emission of light from the light-emitting diode having an extended waveguide thus allowing a narrow beam divergence of the emitted light.

### BRIEF DESCRIPTION OF THE DRAWINGS

FIG. 1 shows a schematic diagram of a prior art light-emitting diode emitting light through the top surface.

FIG. 2 shows a schematic diagram of a prior art light-emitting diode emitting light through an edge facet.

FIG. 3(a) shows a schematic diagram of vertical optical modes in the prior art light-emitting diode of FIG. 2. The fundamental (solid line) and the second-order (dashed-dotted line) optical modes are shown.

FIG. 3(b) shows a schematic diagram of vertical optical modes in the prior art light-emitting diode of FIG. 2. The fundamental (solid line) and the fourth-order (dashed-dotted line) optical modes are shown.

FIG. 3(c) shows a schematic diagram of vertical optical modes in the prior art light-emitting diode of FIG. 2. The fundamental (solid line) and the sixth-order (dashed-dotted line) optical modes are shown.

FIG. 4(a) shows schematically the aluminum content profile in a light-emitting diode based on a GaAs/GaAlAs waveguide.

FIG. 4(b) shows a refractive index profile of a waveguide within a light-emitting device according to one embodiment of the present invention. The profile includes a photonic band crystal and an optical defect.

FIG. 5(a) shows the fundamental (solid line) and the first-order (dashed-dotted line) optical modes in the structure of FIG. 4(b).

FIG. 5(b) shows the fundamental (solid line) and the second-order (dashed-dotted line) optical modes in the structure of FIG. 4(b).

FIG. 5(c) shows the fundamental (solid line) and the third-order (dashed-dotted line) optical modes in the structure of FIG. 4(b).

FIG. 5(d) shows the fundamental (solid line) and the fourth-order (dashed-dotted line) optical modes in the structure of FIG. 4(b).

FIG. 6 shows the far-field diagram of the fundamental optical mode of FIG. 5 showing a narrow beam divergence.

FIG. 7 shows a schematic diagram of a light-emitting diode emitting light through the edge facet based on a photonic band crystal according to one embodiment of the present invention.

FIG. 8 shows a schematic diagram of a light-emitting diode according to another embodiment of the present invention, where light is coming out to the etched-through trenches, is reflected from the trench facets and goes into the vertical direction.

FIG. 9(a) shows schematically a top view of a light-emitting diode chip having a trench of a rectangular shape.

FIG. 9(b) shows schematically a top view of a light-emitting diode chip having a ring-shape trench.

FIG. 10 shows schematically a light-emitting diode according to another embodiment of the present invention where a lateral photonic band crystal is formed which enables the emission of light with a low beam divergence in the lateral plane.

FIG. 11 shows schematically a light-emitting diode according to another embodiment of the present invention where light goes out in the vertical direction.

FIG. 12(a) shows schematically an aluminum composition profile of a diode laser based on a GaAs/GaAlAs photonic band crystal.

FIG. 12(b) shows schematically an aluminum composition profile of a light-emitting diode based on a GaAs/GaAlAs photonic band crystal according to an embodiment of the present invention. FIG. 12(c) shows schematically the fundamental (solid line) and the first-order (dash-dotted line) optical modes of the diode laser of FIG. 12(a).

FIG. 12(d) shows schematically the fundamental (solid line) and the first-order (dash-dotted line) optical modes of the light-emitting diode of FIG. 12(b).

FIG. 12(e) shows schematically the far-field light intensity of the diode laser of FIG. 12(a) below the lasing threshold (solid line) and above the lasing threshold (dash-dotted line).

FIG. 12(f) shows schematically the far-field light intensity of the light-emitting diode of FIG. 12(b).

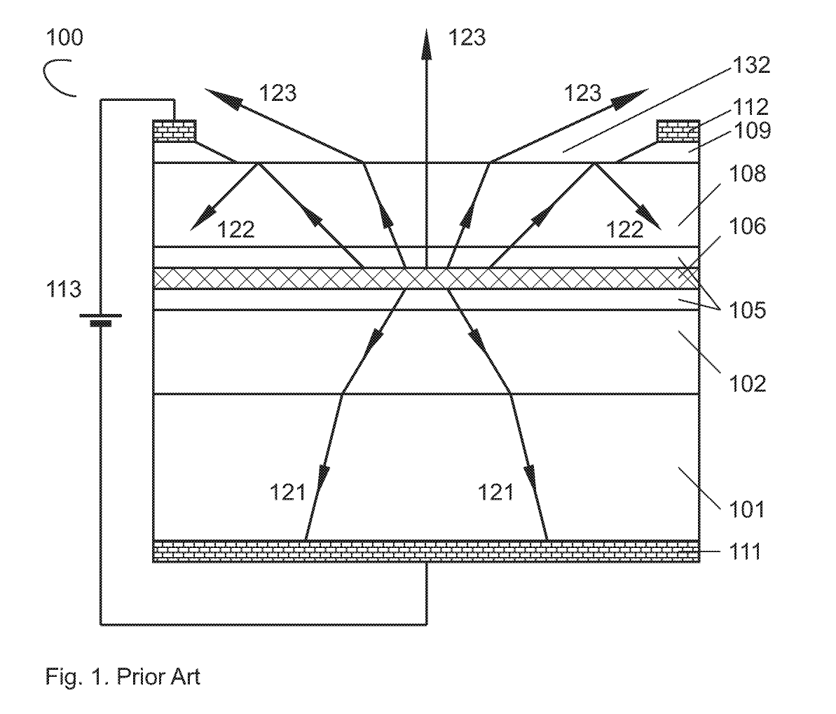

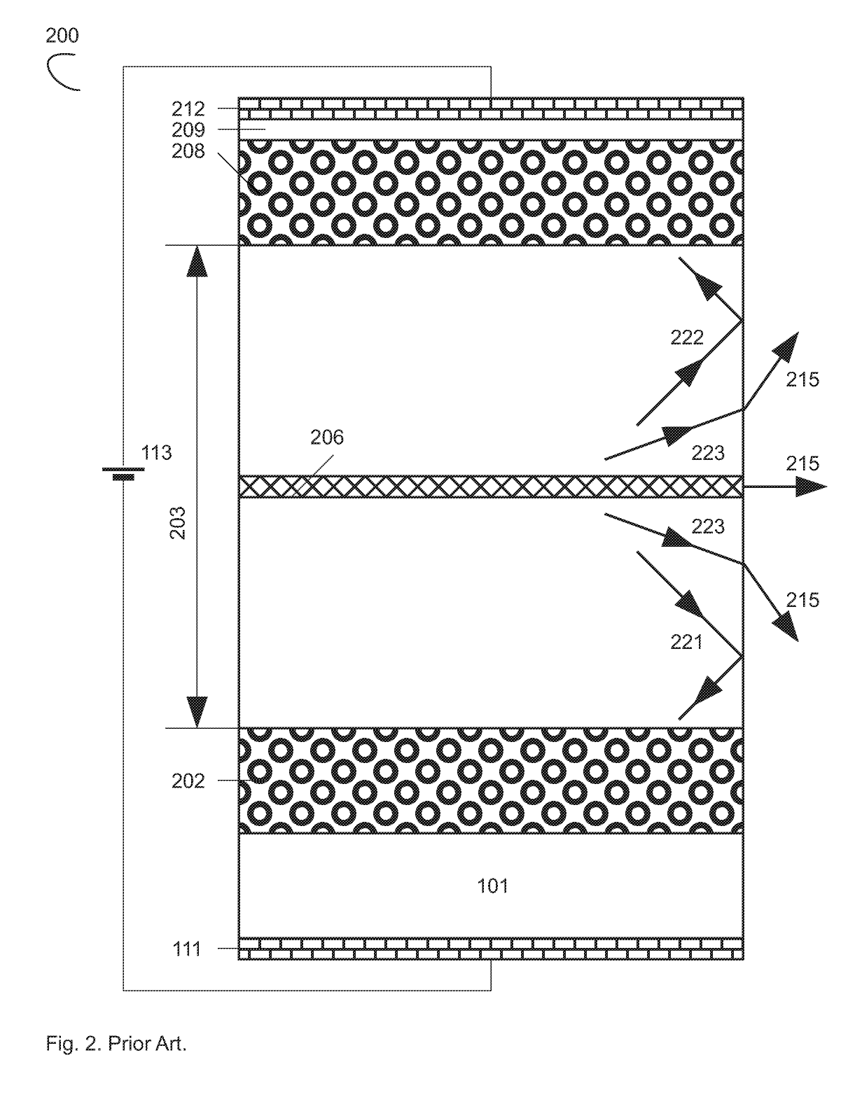

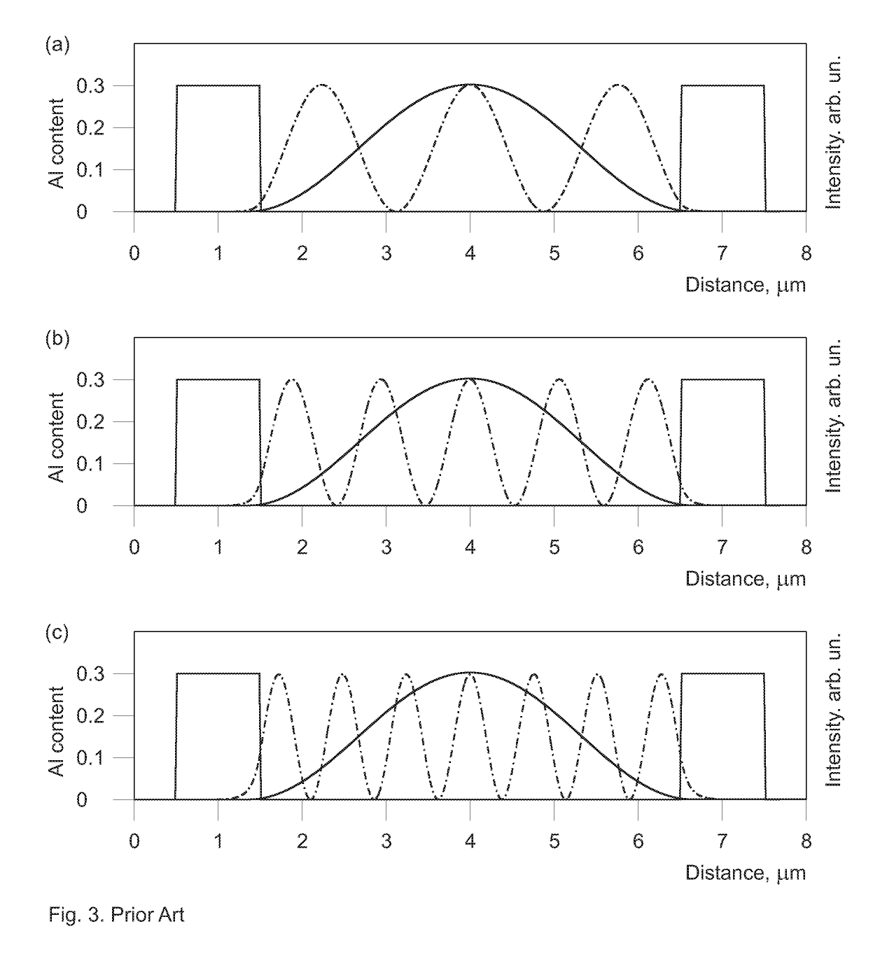

### DETAILED DESCRIPTION OF THE INVENTION

A Longitudinal Photonic Band Crystal Applied to Light-Wmitting Diodes

The present invention obtains a light emitting optolectronic device having a narrow far-field pattern of the radiation. This may be accomplished using an extended waveguide. The main disadvantage of current waveguides is the multi-mode nature of laser radiation that leads to a complex far-field pattern and a wide beam divergence. To suppress the higher modes and, at the same time to provide a reasonable confinement factor of the fundamental mode, a special design of the waveguide is required.

U.S. Pat. No. 6,804,280, issued Oct. 12, 2004 and U.S. Pat. No. 6,996,148, issued Feb. 7, 2006, both by the present inventors and herein incorporated by reference, employed a photonic band crystal in semiconductor diode lasers. The present invention uses a photonic band crystal in light-emitting diodes.

Maximov et al. (M. V. Maximov, Yu. M. Shernyakov, I. I. Novikov, V. A. Shchukin, I. Shamid and N. N. Ledentsov, “Narrow vertical beam divergence laser diode based on longitudinal photonic band crystal waveguide”. Electronics Letters, Volume 39, Issue 24, pp. 1729-1731, Nov. 27, 2003) fabricated a single vertical mode diode laser emitting laser light at the spectral region at 980 nm and demonstrated the vertical beam divergence below 5 degrees. Further, Maximov et al. (M. V. Maximov, Yu. M. Shernyakov, I. I. Novikov, S. M. Kuznetsov, L. Ya. Karachinsky, N. Yu. Gordeev, V. P. Kalosha, V. A. Shchukin and N. N. Ledentsov. “High power GaInP/AlGalnP visible lasers (λ=646 nm) with narrow circular shaped far-field pattern”. Electronics Letters, Volume 41, Issue 13, pp. 741-742, Jun. 23, 2005) fabricated a semiconductor diode laser emitting laser light in the spectral region at 650 nm and demonstrated the vertical and the lateral beam divergence about 8 degrees.

The present invention uses a longitudinal photonic band crystal in light-emitting diodes. The present invention teaches using a photonic band crystal in geometry where the generated light propagates perpendicular to the direction of the refractive index modulation. In particular, for a light-emitting diode of the present invention operating in the edge-emitting geometry, the photonic band crystal is a one-dimensional periodic structure of layers, in which the refractive index n is modulated in the vertical direction z, n=n(z). Then, the electric field strength, say in the TE-modes, can be written in the form:
E_{y}(x, z, t)=E_{y}(z) exp [i(βx−Ωt)}, (1)
where the exp[iβx] represents the propagation along the waveguide in the x-direction, and the amplitude E_{y}(z) depicts the variation of the electric field strength across the waveguide. The latter obeys the wave equation (see, e.g., H. C. Casey, Jr. and M. B. Panish, Semiconductor Lasers, Part A, Academic Press, N.Y., 1978, pp. 32-43 and 70-79):

$$- \frac{{\partial }^{2} {E}_{y}}{\partial {z}^{2}} + [ {β}^{2} - \frac{{ω}^{2}}{{c}^{2}} n ( z ) ] {E}_{y} = 0. \qquad ( 2 )$$

In an infinite, perfectly periodic photonic band crystal, the spectrum includes allowed bands in the frequency Ω and the constant β, for which the electromagnetic waves are periodic waves propagating throughout the crystal, and forbidden gaps, for which no propagation of an electromagnetic wave is possible. In any real system, a perfect periodicity is broken by either termination of a sequence of layers or any type of defect violating the periodical profile of the refractive index. Such a defect can be either localizing or delocalizing for electromagnetic waves in the z-direction. In the case of a localizing defect, two types of electromagnetic waves are possible. These are a) waves localized by the defect in the z-direction and propagating along the waveguide in the x-direction, and b) waves extended over the photonic band crystal in the z-direction and propagating along the waveguide in the x-direction.

Therefore, the light-emitting diode of the present invention operating in the edge-emitting geometry includes two primary elements: 1) a photonic band crystal with the refractive index modulation in a vertical direction and 2) a defect in which the active region of the light-emitting diode is preferably placed. The photonic band crystal and its defect are designed in such a way that one and only one optical mode of the light-emitting diode is localized by the defect and decays away from the defect in the z-direction while the other modes are extended in the z-direction over the photonic band crystal.

The ability of the defect to localize modes of laser radiation is governed by two parameters. The first parameter is the difference between the refractive indices of the defect and the reference layer of the photonic band crystal, Δn. The second parameter is the volume of the defect. For the light emitting diodes of the present invention, in which the refractive index is modulated in one direction only, n=n(z), the second parameter is the thickness of the defect. Generally, as the value of Δn increases at a fixed defect thickness, the number of modes being localized by the defect also increases. As the thickness of the defect increases at a fixed Δn, the number of modes being localized by the defect also increases. The design of the light-emitting diodes (LEDs) of the present invention chooses these two parameters, Δn and the thickness of the defect, so that one and only one mode of the LED is localized by the defect. The other modes are extended modes in the z-direction over the photonic band crystal.

A preferred embodiment of the invention provides a light-emitting diode with an active region placed in the optical defect region of the waveguide where the fundamental mode of the device is localized. The required localization length of the fundamental mode is determined by the interplay of two tendencies. On the one hand, the localization length needs to be large enough to provide a low far-field beam divergence. On the other hand, the localization length should be sufficiently shorter than the length of the photonic band crystal. This provides efficient localization of the fundamental mode on the scale of the total thickness of the photonic band crystal and therefore a significant enhancement of the electric field strength in the fundamental mode compared to that of the other modes.

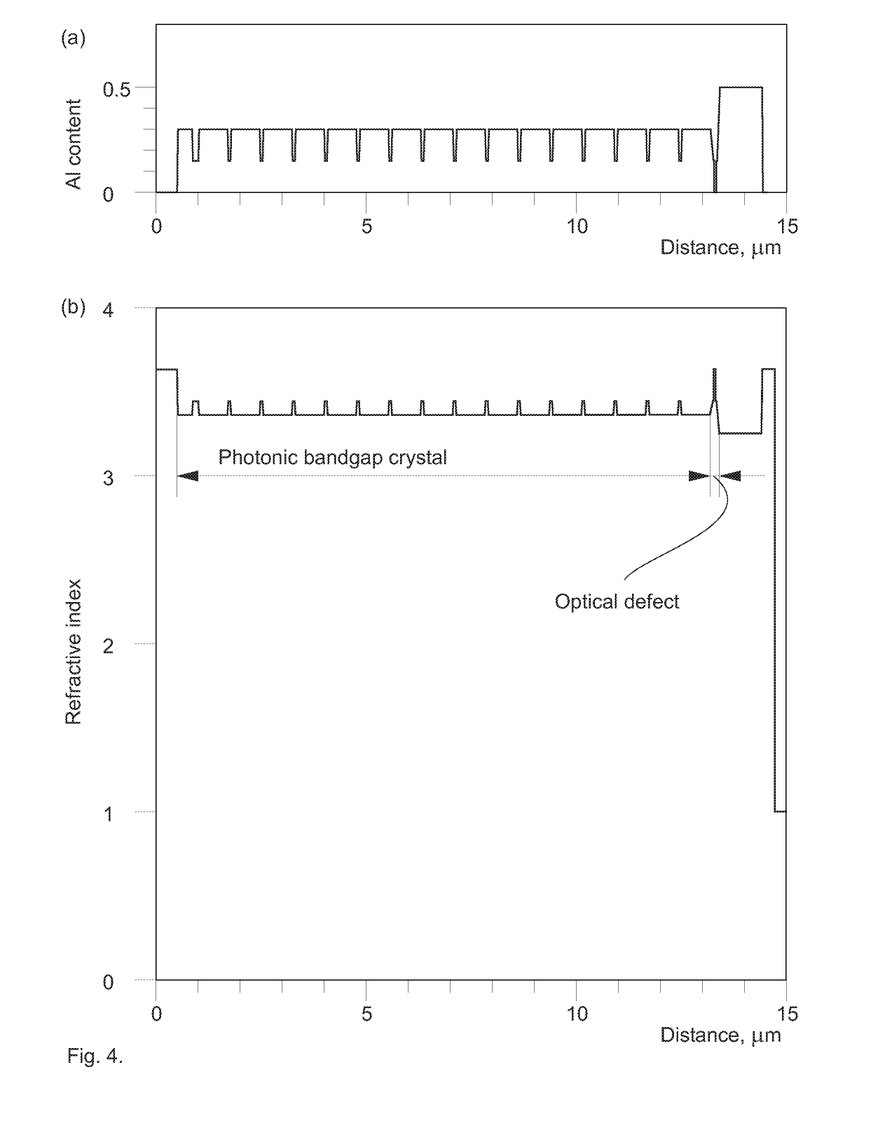

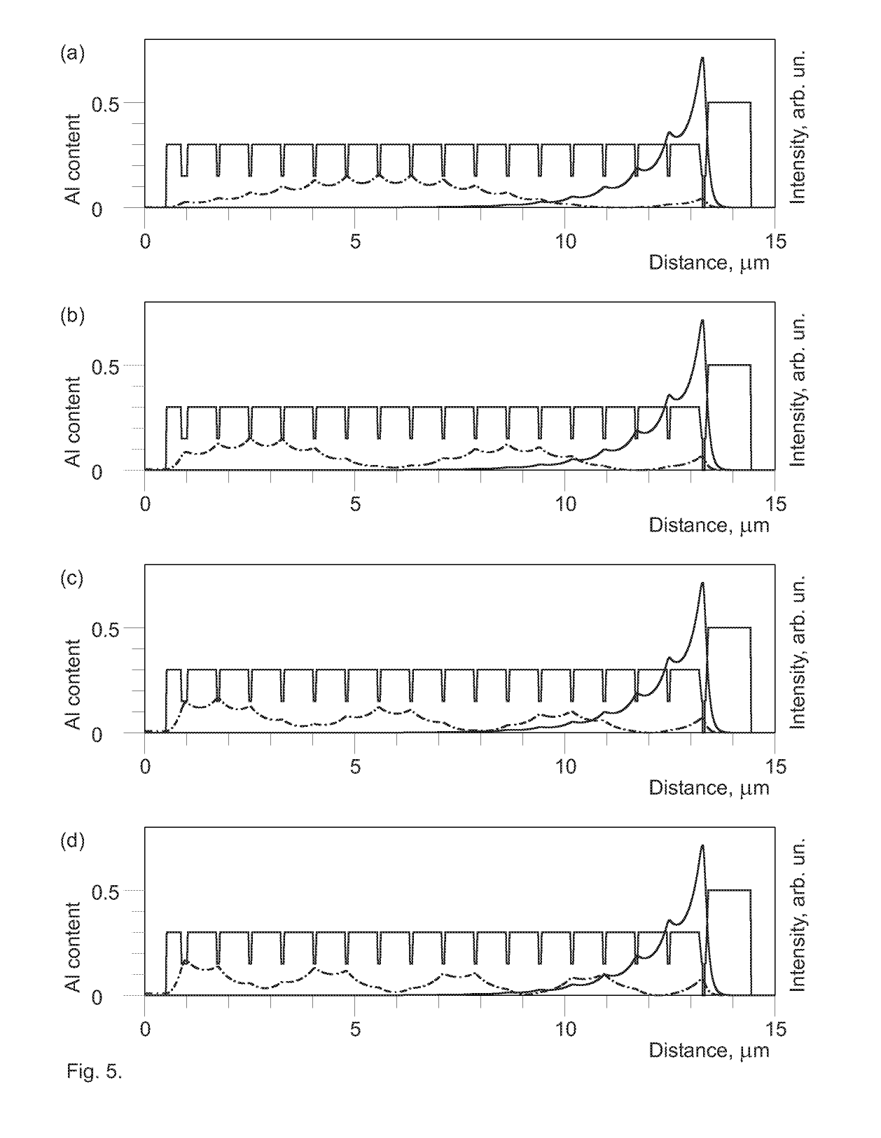

FIGS. 4(a) and 4(b) illustrate the concept of a photonic band crystal according to the present invention. More specifically, FIG. 4(a) shows schematically the aluminum content profile in a light-emitting diode based on a GaAs/GaAlAs waveguide and FIG. 4(b) shows a refractive index profile including a photonic band crystal and an optical defect. FIGS. 5(a) through 5(d) show the spatial profile of a few optical modes in the structure of FIG. 4(b) including a photonic band crystal and an optical defect of the photonic band crystal. More specifically, FIGS. 5(a) through 5(d) each show the fundamental optical mode (solid line). In addition, FIG. 5(a) shows the first-order (dashed-dotted line) optical mode, FIG. 5(b) shows the second-order (dashed-dotted line) optical mode, FIG. 5(c) shows the third-order (dashed-dotted line) optical mode, and FIG. 5(d) shows the fourth-order (dashed-dotted line) optical mode.

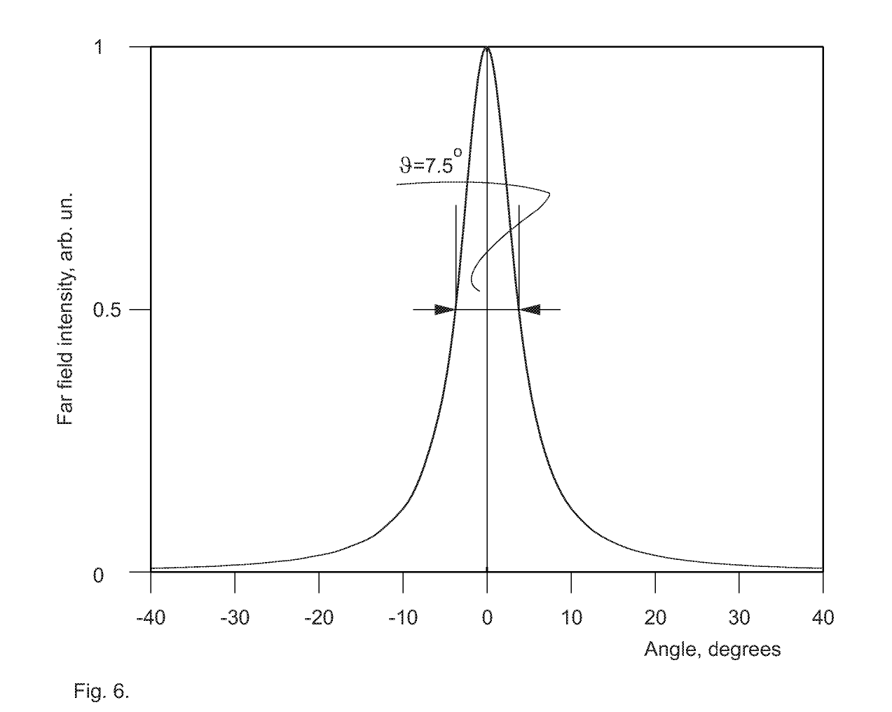

FIGS. 5(a) through 5(d) show that the intensity of the fundamental mode within the optical defect exceeds the intensity of any other mode at least by an order of magnitude. A particular embodiment of the light-emitting device based on the waveguide of FIGS. 4 and 5 shows a beam divergence of 7.5°, as is demonstrated by the far field profile of the fundamental optical mode shown in FIG. 6.

Light-Emitting Diode Versus Laser

There is a key difference between a diode laser based on a photonic band crystal disclosed in U.S. Pat. No. 6,804,280, issued Oct. 12, 2004 and U.S. Pat. No. 6,996,148, issued Feb. 7, 2006, on the one hand, and a light-emitting diode based on a photonic band crystal disclosed in the present application, on the other hand. These patents are herein incorporated by reference.

Any diode laser operates as a light-emitting diode below the lasing threshold. And the far field pattern of light emitted by a light-emitting diode is generally broad, whether the far-field pattern of the same device in the lasing mode is broad or narrow.

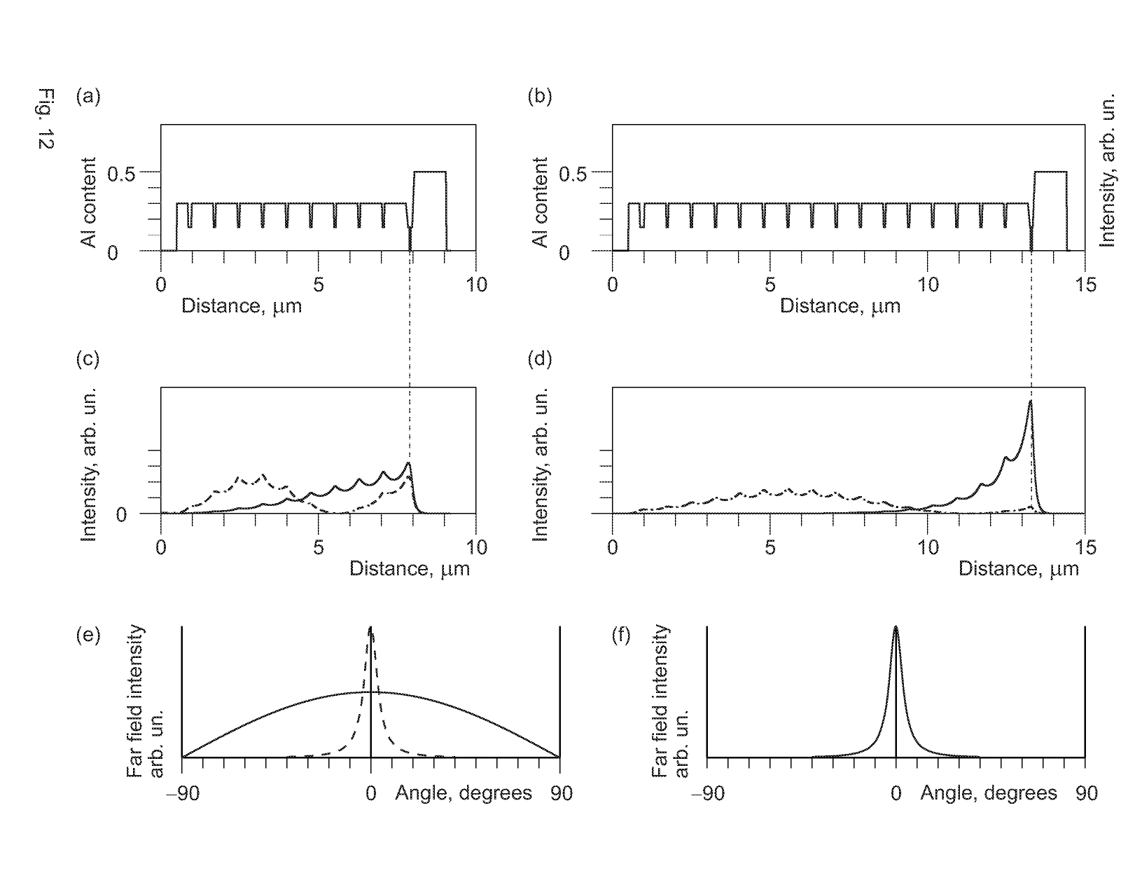

FIG. 12 demonstrates a comparison of a laser and a light-emitting diode, both being based on a photonic band crystal. FIG. 12(a) shows schematically an aluminum composition profile of a GaAs/GaAlAs laser based on a photonic band crystal. FIG. 12(b) shows schematically an aluminum composition profile of a GaAs/GaAlAs light-emitting diode based on a photonic band crystal.

FIG. 12(c) shows schematically the fundamental vertical mode (solid line) and the first-order vertical mode of the laser of FIG. 12(a). The optical confinement factor of the fundamental mode exceeds that of the excited mode only slightly. In the particular example of FIG. 12(c) the optical confinement factors of two modes in the active region differ only by approximately 25%. This may be sufficient that the lasing occurs only in the fundamental mode, and the far-field intensity of the emitted light is narrow (dashed line in FIG. 12(e)). However, below lasing threshold, all modes having a comparable optical confinement factor in the active region, will contribute to the emission of light. The far-field of the emitted light will be broad (solid line in FIG. 12(e)). One may roughly estimate the emission of light in all directions with equal probability which results in the far-field pattern proportional to cos υ, where υ is the angle between the normal to the front facet of the device and the direction between the light-emitting diode and photodetector measuring the intensity of light.

FIG. 12(d) shows schematically the fundamental vertical mode (solid line) and the first-order vertical mode of the laser of FIG. 12(a) repeating basically FIG. 5(a). The optical confinement factor of the fundamental mode exceeds that of the first-order mode approximately by a factor of ten. In this case, the far-field pattern of light emitted below the lasing threshold will be dominated by the fundamental mode and will, therefore, be narrow as shown in FIG. 12(f).

Generally speaking, the requirements on the discrimination of optical modes are much more tough for a light-emitting diode than for a laser. To fabricate a light-emitting diode with a narrow beam divergence is a much more challenging task than to fabricate a laser with a narrow beam divergence. The optical confinement factor of the fundamental mode in the active region of a light-emitting diode should exceed that of any of the rest of the optical modes at least by the factor of three. If some structure is selected to operate as a laser based on a photonic band crystal, one may select another structure for a light-emitting diode with a narrow beam. One of the preferred ways to select a light-emitting diode is to increase the length of the photonic band crystal, e.g., by increasing the number of periods, as is done on FIG. 12(b) compared to FIG. 12(a).

### Preferred Embodiments

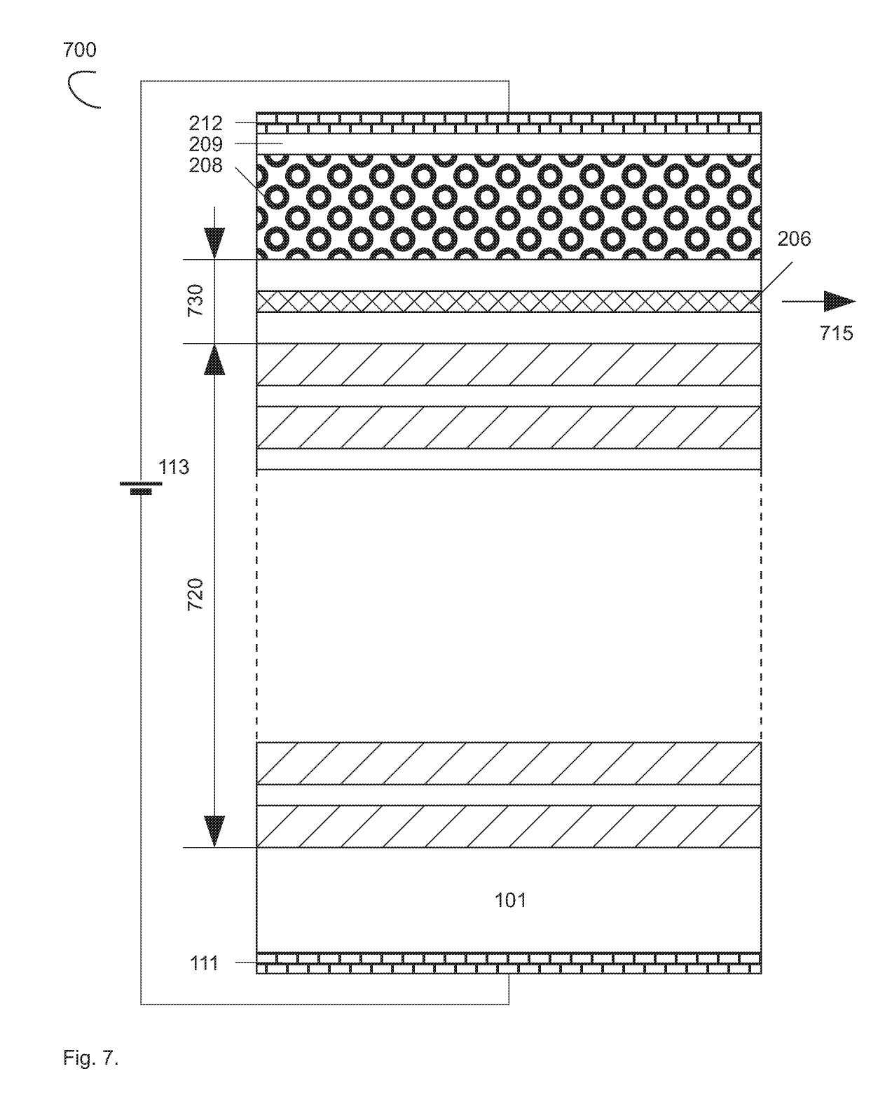

FIG. 7 shows schematically a structure of a light-emitting diode (700) according to one embodiment of the present invention. The device is grown epitaxially preferably on an n-doped substrate (101). The structure sandwiched between the substrate (101) and a p-doped cladding layer (208) includes an n-doped photonic band crystal (720) and an optical defect (730). An active region (206) is preferably located within the optical defect (730). The p-contact layer (209) is located on top the p-cladding layer (208). An n-contact (a bottom contact) (111) is mounted on a substrate (101) on the side opposite to the photonic band crystal (720). The p-contact (212) is mounted atop the p-contact layer (209). The photonic band crystal (720) and the optical defect (730) are selected such that only one vertical optical mode of the device is localized at the optical defect and decays away from the defect, whereas all other vertical optical modes are extended over the entire photonic band crystal. Light (715) is emitted in the lateral direction.

In a preferred embodiment, a photonic band crystal is a periodic structure of layers, where each period includes one layer with a first refractive index, n₁, and one layer with a second refractive index, n₂, and n₂<n₁.

Other embodiments also realize an optical defect localizing optical modes. In one embodiment, a defect is one of the periods of the photonic band crystal, in which a layer having the refractive index n₁ is replaced by a layer having a higher refractive index, n₃>n₁. In another embodiment, a layer having the refractive index n₂ is replaced by a layer having a refractive index n₄, where n₄>n₂. In another embodiment, a layer having a higher refractive index n₁ within a defect has a larger thickness than the layers with the same index in the photonic band crystal. In yet another embodiment, a layer having a lower refractive index, n₂, within a defect has a smaller thickness than the layers with the same index within the photonic band crystal. Various other embodiments are possible where a deviation of the refractive index profile from the periodic one is such that one and only one optical mode is localized by the optical defect.

In another embodiment, a layer is added to a photonic band crystal on the side remote from the optical defect. This layer does not affect the localized optical mode. All other modes extended over the photonic band crystal are extended also over the additional layer. Therefore, the intensity of those modes within the optical defect is further reduced, whereas the intensity of the localized fundamental mode is not changed. This increases the discrimination of the optical modes.

In another embodiment, a substrate may play the role of this additional layer. As the substrate is typically 100 to 300 μm thick, this further enhances the discrimination between the fundamental mode and high-order modes in the optical confinement factor.

A light-emitting diode operates typically under conditions when the active region is still absorbing (one exception is a light-emitting diode in the superluminescent mode, where optical gain occurs in the active region.). Therefore, the length of the device is preferably smaller than the absorption length, which is typically a few tens of micrometers.

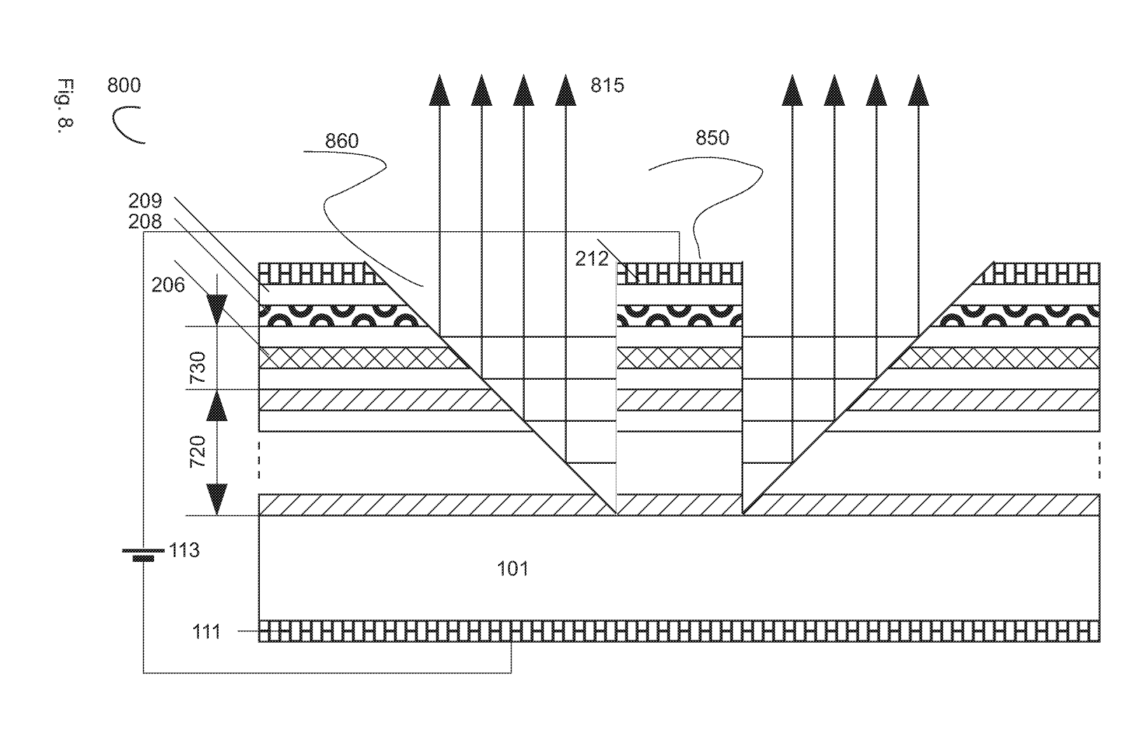

FIG. 8 shows schematically a further embodiment of the present invention, where the length of the device is selected to be shorter than the absorption length. The device (800) is a light-emitting diode comprising a photonic band crystal (720) and an optical defect (730). The discrimination of the optical modes results in light being generated only in the one fundamental vertical optical mode. Light generated in this mode propagates along the waveguide. The waveguide is etched forming trenches (860). The trenches are preferably etched through the entire photonic band crystal (720). The bias (113) is applied to a short section (850), the length of which is preferably shorter than the absorption length. Light in the fundamental optical mode comes out of the section (850) having a narrow beam divergence, i.e., nearly a parallel beam. Trenches (860) are etched to have such a profile that the light in the fundamental vertical mode is reflected from the surfaces of the trenches and is emitted in the vertical direction (815) still having a low beam divergence.

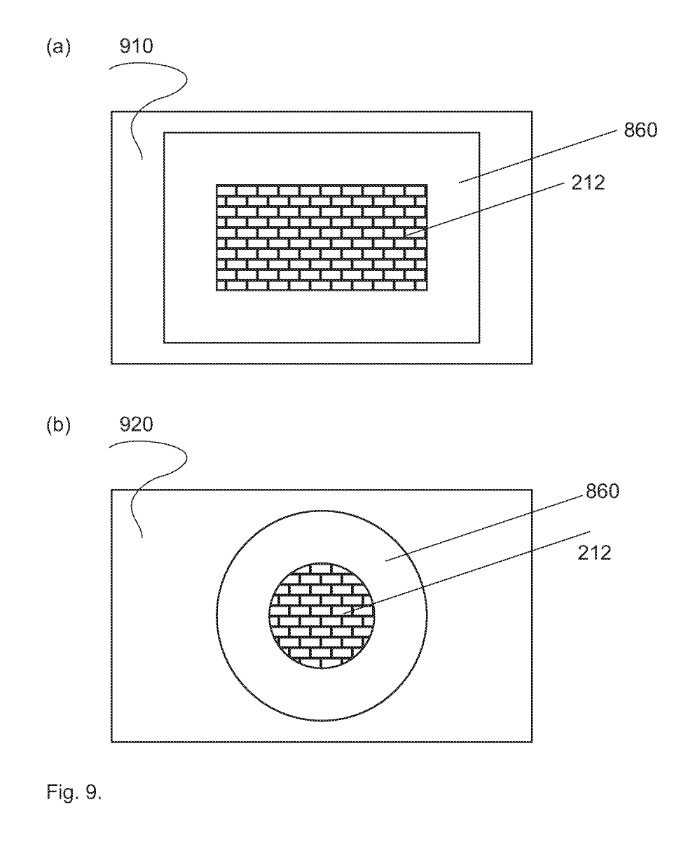

FIG. 9(a) shows schematically a top view of a light-emitting diode chip (910), on which a trench (860) has a rectangular shape around the active section covered by a top contact (212).

FIG. 9(b) shows schematically a top view of a light-emitting diode chip (920), on which a trench (860) has a circular shape around the active section covered by a top contact (212).

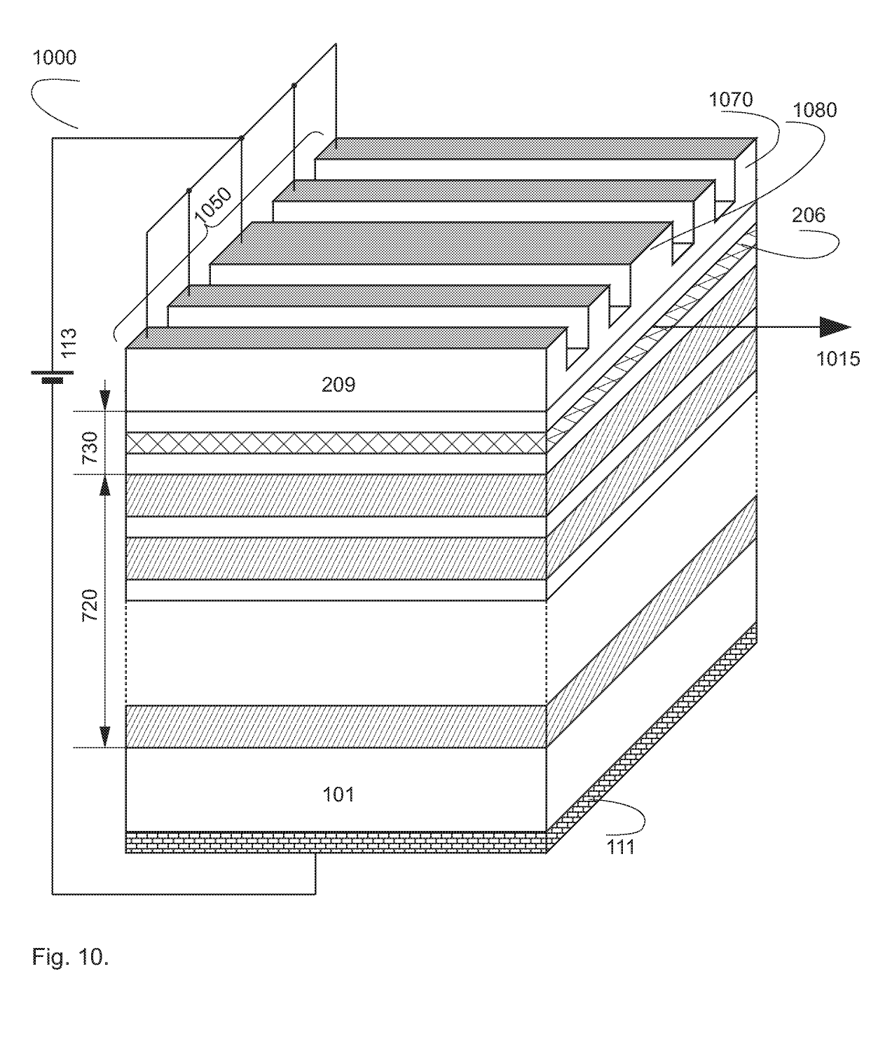

FIG. 10 shows a light-emitting diode (1000) according to another embodiment of the present invention. A set of ridges (1050) is formed preferably atop the p-contact layer (209). The height of the ridges, the width of each ridge, and the spacing between each two neighboring ridges are selected such that a lateral photonic band crystal with a lateral optical defect is realized. In a preferred embodiment, the width of one ridge (1080) exceeds the width of the other ridges (1070). The depth of the ridges, the width of one selected ridge (1080), the width of the rest of the ridges (1070), and the spacing between the ridges are selected such that only one lateral optical mode is localized at the ridge (1080) and decays in the lateral plane away from the ridge (1080), whereas the other lateral optical modes are extended throughout the entire lateral plane. Therefore the optical confinement factor of one lateral optical mode, preferably of the fundamental optical mode, is significantly larger than that of the rest of the optical modes. Thus, device operation in a single lateral mode can be realized. The selection of the height of the ridges, of the width of the ridges and of the spacing between the ridges allows the realization of the light output with a low lateral beam divergence. The device allows an independent selection of the vertical optical modes and the lateral optical modes, and, thus the control of the beam shape of the outgoing light (1015). In other words, it is possible to control independently the far field beam divergence in both the vertical and lateral directions. In one embodiment, a circular beam may be obtained.

The top contacts are mounted atop the ridges. In the preferred embodiment, the forward bias (113) is applied to the active region through the top contacts on each ridge. In another embodiment, the bias is applied to the contacts on one selected ridge (1080), or to the contacts on a few ridges close to the selected ridge (1080), whereas no bias is applied to the ridges on the peripheries of the device (1000). Then, the active region beneath the ridges to which no bias is applied is absorbing, where a low or a moderate absorption can be realized. Then the selected lateral mode, which is localized in the lateral plane at the lateral optical defect, decays significantly away from the defect in the lateral plane and is not absorbed at the peripheries of the device. The other lateral modes, which are extended in the lateral plane throughout the entire device, are absorbed. This enhances additionally the selectivity of the lateral modes.

In other embodiments of the present invention, trenches are fabricated on top of the device (1000) to ensure the light output in the vertical direction having a low beam divergence.

In yet another embodiment of the present invention, a superluminescent light-emitting diode is fabricated based on a lateral photonic band crystal with a lateral optical defect, where the lateral photonic band crystal and the lateral optical defect are selected such that the device emits light in a single lateral mode and the emitted light has a low lateral beam divergence.

In a further embodiment of the present invention, a superluminescent light-emitting diode fabricated on the basis of a lateral photonic band crystal with a lateral optical defect, which emits light in a single lateral mode, and has a low lateral beam divergence, operates in a lasing mode.

Additional embodiments of the present invention include a photonic band crystal with a refractive index modulation perpendicular to the propagation of light, as in all the embodiments of the present invention, but light propagates perpendicular to the plane of the p-n junction. This embodiment is preferably a light-emitting diode emitting light in the vertical direction, where the structure of the device resembles the structure of a vertical cavity surface emitting laser (VCSEL).

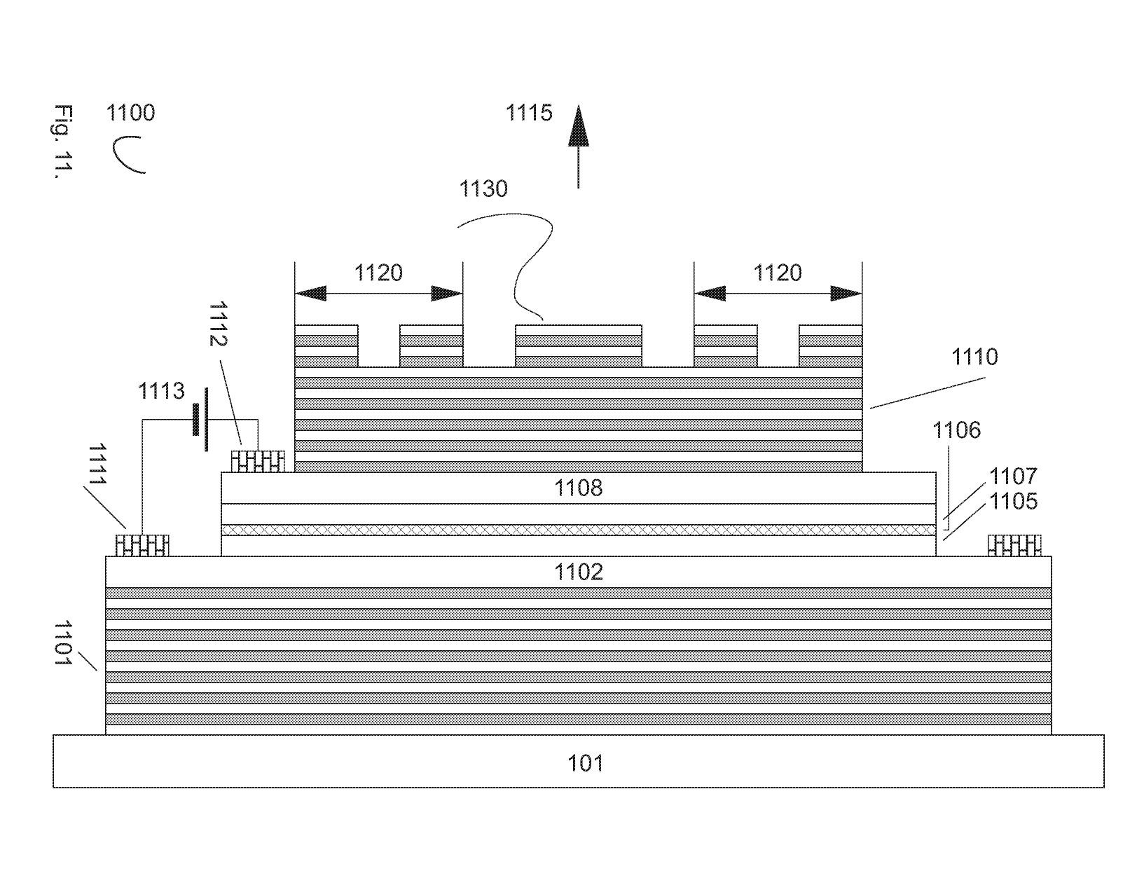

Referring specifically to FIG. 11, an example of a light-emitting diode (LED) (1100) is shown using a photonic band crystal (1120) in accordance with the present invention. FIG. 11 shows a specific realization of a photonic band crystal with a refractive index modulation perpendicular to the direction of light propagation. The structure is grown epitaxially on the substrate (101). The substrate (101) is preferably formed from any III-V semiconductor material or III-V semiconductor alloy, e.g. GaAs, InP, GaSb, or others, as in the other embodiments of the present invention. In a preferred embodiment, GaAs is used. Bragg reflectors are preferably used for the bottom mirror (1101). The rest of the LED (1100) includes two primary elements: 1) an active element above the bottom mirror (1101) and 2) a top mirror (1110) including the photonic band crystal (1120) and the optical defect (1130).

The active element (1106) is preferably surrounded by a weakly n-doped layer (1105) and a weakly p-doped layer (1107). The weakly n-doped layer (1105) is placed between the n-doped current spreading layer (1102) and the active element (1106). The weakly p-doped layer (1107) is placed between the p-doped current spreading layer (1108) and the active element (1106). The first metal contact (1111) is mounted on the n-doped current spreading layer (1105). The second metal contact (1112) is mounted on the p-doped current spreading layer (1108).

The active element (1106) is preferably formed by any insertion, the energy band of which is narrower than that of the layers constituting the bottom mirror (1101) and the top mirror (1110). Possible active elements include, but are not limited to, a single-layer or a multi-layer system of quantum wells, quantum wires, quantum dots, or their combination. In a case of the device on a GaAs-substrate, preferred materials for the active element include, but are not limited to, a system of insertions of InAs, In₁₋ₓGaₓAs, InₓGa_{1-x-y}Al_{y}As, InₓGa₁₋ₓAs_{1-y}N_{y} or similar materials.

The n-doped layer (1102) is preferably formed from a material lattice-matched or nearly lattice-matched to the substrate (101), transparent to the generated light, and doped by donor impurities. It is preferably made of the same material as one of the layers of the n-doped photonic band crystal (720) in the other embodiments. The p-doped layer (1108) is preferably formed from the material lattice-matched or nearly lattice-matched to the substrate, transparent to the generated light and doped by acceptor impurities. It is preferably made of the same material as the p-cladding layer (208) in the other embodiments. The n-contact (1111) is preferably formed from the same material as the n-contact (101) in the other embodiments. The p-contact (1112) is preferably formed from the same material as the p-contact (112) in the other embodiments.

The n-doped current spreading layer (1102) preferably sits directly on top of the bottom mirror (1101). The top mirror (1110) is preferably subject to selective etching such that a thicker part of the mirror (1130) has a larger lateral dimension than the thicker parts in the photonic band crystal (1120). The lateral fundamental mode can be designed to have the maximum overlap with the light generating region. The characteristic period of the top grating is preferably in the range of 1 to 2 μm. The width of the etching depth (or deposit profile) is preferably about 0.1 to 0.5 μm. The central pedestal above the aperture region is broader by preferably 5 to 10% as compared to all neighboring periods.

The active element (1106) emits light when a forward bias (1113) is applied. Light comes out (1115) in the lateral fundamental optical mode.

In another embodiment of the present invention, a semiconductor light-emitting diode emitting light from the surface, like the one of FIG. 11, comprises one top Bragg reflector. In another embodiment of the present invention, an element representing a photonic band crystal comprises a plurality of optical defects. In yet another embodiment of the present invention, the plurality of optical defects form a two-dimensional periodic lattice.

In other embodiments of the light-emitting diode, the photonic band crystal is formed by selective etching without overgrowth, by dielectric or metallic coating of the surface, or other patterning techniques. Any type of patterning used in these embodiments must promote a localization of the fundamental lateral optical mode at the defect and thus obtain a significant overlap integral of the active medium with one and only one mode. All these approaches enable effective emission of light in single mode.

It is appreciated that certain features of the invention, which are, for clarity, described in the context of separate embodiments, may also be provided in combination in a single embodiment. Conversely, various features of the invention, which are, for brevity, described in the context of a single embodiment, may also be provided separately or in any suitable subcombination.

All publications, patents and patent applications mentioned in this specification are herein incorporated in their entirety by reference into the specification, to the same extent as if each individual publication, patent or patent application was specifically and individually indicated to be incorporated herein by reference. In addition, citation or identification of any reference in this application shall not be construed as an admission that such reference is available as prior art to the present invention.

Although the invention has been illustrated and described with respect to exemplary embodiments thereof, it should be understood by those skilled in the art that the foregoing and various other changes, omissions and additions may be made therein and thereto, without departing from the spirit and scope of the present invention. Therefore, the present invention should not be understood as limited to the specific embodiments set out above but to include all possible embodiments which can be embodied within a scope encompassed and equivalents thereof with respect to the feature set out in the appended claims.

What is claimed is:

1. A semiconductor light-emitting diode comprising:
a) an n-doped region, at least a part of which comprises a photonic band crystal including a layered structure comprising at least one layer, wherein each layer is doped by an n-typed impurity, wherein the layered structure has a periodically modulated refractive index, wherein the periodically modulated refractive index is modulated in the direction perpendicular to a direction of light propagation;
b) an optical defect contiguous with said photonic band crystal, comprising a light generating layer that emits light when exposed to an injection current when a forward bias is applied;
c) a p-doped layered structure comprising at least one layer, wherein each layer is doped by a p-type impurity, and wherein said p-doped layered structure is located on a side of said optical defect opposite said n-doped region, wherein the p-doped layered structure has a variable refractive index that hinders an extension of a fundamental mode to at least one doped layer within the p-doped layered structure and to a p-contact;
wherein the fundamental optical mode is localized by the optical defect, while all other modes are extended over the photonic band crystal; and
wherein a total thickness of said photonic band crystal and said optical defect provides a low beam divergence for the localized optical mode.

2. The semiconductor light-emitting diode of claim 1, wherein an optical confinement factor of the localized optical mode exceeds the optical confinement factor of the other optical modes by at least a factor of three, which ensures that a width of the light beam emitted by the light-emitting diode is predominantly defined by the localized optical mode having a low beam divergence, and thus has also a low beam divergence.

3. The semiconductor light-emitting diode of claim 1, further comprising:
d) an n-emitter contiguous with said photonic band crystal remote from said optical defect;
e) a substrate contiguous with said n-emitter remote from said optical defect; and
f) an n-contact contiguous with said substrate remote from said optical defect.

4. The semiconductor light-emitting diode of claim 3, further comprising:
g) a p-emitter contiguous with said p-doped layered structure remote from said optical defect; and
h) a p-contact contiguous with said p-emitter remote from said optical defect.

5. The semiconductor light-emitting diode of claim 1, wherein said optical defect further comprises:
ii) a first active element layer located on an n-side of the light generating layer;
iii) a second active element layer located on a p-side of the light generating layer;
iv) a thick n-doped layer contiguous with said first active element layer remote from said light generating layer; and
v) a thick p-doped layer contiguous with said second active element layer remote from said light generating layer.

6. The semiconductor light-emitting diode of claim 5, wherein said first active element layer is formed from a material selected from the group consisting of a weakly-doped n-layer and an undoped layer.

7. The semiconductor light-emitting diode of claim 5, wherein said second active element layer is formed from a material selected from the group consisting of a weakly-doped p-layer and an undoped layer.

8. The semiconductor light-emitting diode of claim 1, wherein the layered structure of the photonic band crystal comprises a periodic alternation of a first layer having a high refractive index and a second layer having a low refractive index.

9. The semiconductor light-emitting diode of claim 8 wherein said optical defect further comprises a region contiguous with said light generating layer on both sides, wherein said region has a refractive index which is the same as the refractive index of the first layer of the photonic band crystal, and said region is thicker than each of said first layers of the photonic band crystal.

10. The semiconductor light-emitting diode of claim 8 wherein said optical defect further comprises a region contiguous with said light generating layer on both sides, wherein said region has a same thickness as the first layer of the photonic band crystal and a refractive index higher than said first layer of the photonic band crystal and said second layer of the photonic band crystal.

11. The semiconductor light-emitting diode of claim 8 wherein said optical defect further comprises the first layer of said photonic band crystal contiguous with said optical defect, a third layer with a low refractive index contiguous with said first layer remote from said photonic band crystal, and a fourth layer having a high refractive index contiguous with said third layer remote from said photonic band crystal, wherein said fourth layer is thinner than the second layers of the photonic band crystal.

12. The semiconductor light-emitting diode of claim 8 wherein said optical defect further comprises the first layer of said photonic band crystal contiguous with said optical defect, a third layer with a refractive index intermediate between that of the first layer and the second layer of the photonic band crystal contiguous with said first layer remote from said photonic band crystal, and a fourth layer having a high refractive index contiguous with said third layer remote from said photonic band crystal.

13. The semiconductor light-emitting diode of claim 1 wherein said optical defect extends over several periods of the photonic band crystal.

14. The semiconductor light-emitting diode of claim 1 where the photonic band crystal includes an a periodic modulation of the refractive index.

15. The semiconductor light-emitting diode of claim 1, further comprising at least one absorbing layer that absorbs light and is located within one of the first layers of the photonic band crystal.

16. The semiconductor light-emitting diode of claim 15, wherein there are a plurality of absorbing layers such that each absorbing layer is located within a different period of the photonic band crystal.

17. The semiconductor light-emitting diode of claim 1 wherein at least one heterojunction in a doped region is realized by a graded layer.

18. The semiconductor light-emitting diode of claim 1, wherein the lateral dimensions of the light-generating layer are smaller than the absorption length.

19. The semiconductor light-emitting diode of claim 18, wherein the lateral dimensions of the light -generating layer are smaller than one hundred micrometers.

20. The semiconductor light-emitting diode of claim 19, wherein the lateral dimensions of the light-generating layer are smaller than thirty micrometers.

21. The semiconductor light-emitting diode of claim 20, wherein the lateral dimensions of the light-generating layer are smaller than ten micrometers.

22. The semiconductor light-emitting diode of claim 18, wherein the lateral dimensions of the light-generating layer are limited by a trench.

23. The semiconductor light-emitting diode of claim 22, wherein a depth of the trench is selected such that a major part of the optical power of the vertical fundamental optical mode comes out into the etched trench.

24. The semiconductor light-emitting diode of claim 23, wherein a major part of the optical power is at least fifty percent of the optical power.

25. The semiconductor light-emitting diode of claim 22, wherein a profile of the trench is selected such that light in the fundamental mode coming out into the trench reflects from side surfaces of the trench and go further in the vertical direction forming a light beam with a low divergence.

26. The semiconductor light-emitting diode of claim 4, further comprising:
a set of ridges formed on top of the said p-emitter, wherein the set of ridges includes:
a) a lateral photonic band crystal including a structure comprising at least one ridge; and
b) a lateral optical defect contiguous with said lateral photonic band crystal, wherein the lateral optical defect comprises at least one ridge;
wherein the lateral fundamental optical mode is localized by the lateral optical defect, while all other lateral optical modes are extended over the lateral photonic band crystal;
wherein a height of the ridge, a width of said lateral photonic band crystal and said lateral optical defect provides a low lateral beam divergence.

27. The semiconductor light-emitting diode of claim 26, wherein the light-emitting diode operates as a superluminescent light-emitting diode.

28. The semiconductor light-emitting diode of claim 27, wherein the superluminescent light-emitting diode operates in a lasing mode.

29. The semiconductor light-emitting diode of claim 26, wherein an output light beam has a circular shape.

30. A semiconductor light-emitting diode which allows light to propagate in a direction perpendicular to a p-n junction, comprising:
a) a substrate;
b) a bottom mirror formed by a Bragg reflector region above said substrate;
c) an active element above said bottom mirror, comprising:
i) a light generating layer that emits light when exposed to an injection current when a forward bias is applied;
ii) an n-doped current spreading region above said substrate and below said light generating layer;
iii) a p-doped current spreading region above said light generating layer; and
iv) an active element bias control device between said n-doped current spreading region and said p-doped current spreading region such that current can be injected into said light generating layer to generate light; and
d) a photonic band crystal above said active element comprising:
i) a region in which a refractive index is modulated in a direction perpendicular to a direction of light propagation; and
ii) an optical defect, wherein said optical defect localizes a lateral fundamental mode of radiation.

31. The semiconductor light-emitting diode of claim 30 further comprising:
e) a top mirror formed by a Bragg reflector sandwiched between said active element and said element representing said photonic band crystal.

32. The semiconductor light-emitting diode of claim 30, wherein said photonic band crystal comprises a plurality of optical defects.

33. The semiconductor light-emitting diode of claim 32, wherein said plurality of optical defects form a two-dimensional periodic lattice.
